(19) United States
(12) Patent Application Publication
(10) Pub. No.: US 2010/0074291 A1
(43) Pub. Date: Mar. 25, 2010

(54) Distributed Feedback Semiconductor Laser Device

(75) Inventor: Koji Nakamura, Saitama (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/529,029

(22) PCT Filed: Feb. 7, 2008
(86) PCT No.: PCT/JP2008/052031

§ 371 Date: Aug. 28, 2009

(30) Foreign Application Priority Data
Mar. 15, 2007 (JP) 2007-066693

(51) Int. Cl. H01S 5/12

(52) U.S. Cl. 372/45.01; 372/96; 372/46.01; 372/50.11

(57) ABSTRACT

A DFB laser device which can reduce influence of reflected return light and improve output characteristics and can provide a small-sized and inexpensive optical module when mounted on the optical module. The GC-DFB laser device (10) includes a semiconductor substrate (100), a waveguide layer (104) and an active layer (106) formed on one surface side of the semiconductor substrate, and a diffraction grating structure (102) which is formed on one surface of the waveguide layer and has a gain periodically varying in an optical waveguiding direction; wherein the active layer is disposed so as to adjoin the waveguide layer, a band gap wavelength of the waveguide layer is within ±0.1 μm of an oscillation wavelength of the active layer, a thickness of the waveguide layer is in a range of 5 to 30 nm, and a width of the active layer is in a range of 0.7 to 1.0 μm.

### TECHNICAL FIELD

The present invention relates to a gain-coupled (Gain Coupled: GC) distributed feedback (Distributed FeedBack: DFB) semiconductor laser device.

### BACKGROUND ART

A distributed feedback semiconductor laser device (DFB laser device) is a laser device including a diffraction grating disposed on a surface of or on a surface side of a semiconductor substrate and having wavelength selectivity characteristics so that only a specific laser light is fed back by the diffraction grating. Further, since the DFB laser device oscillates at a single mode wavelength, it is widely used as a light source for optical communications.

Conventionally, a DFB laser device as a light source for optical communications is mainly an index-coupled (Index Coupled: IC) DFB laser device. Since the IC-DFB laser device is easily affected by the reflected return light from outside, when an optical module is assembled using it, it is necessary to mount an optical isolator for attenuating the reflected return light from outside. An optical module which eliminates the need for an optical isolator is requested in the specification of GE-PON (Gigabit Ethernet® Passive Optical Network) system requiring low cost and small size, because an optical isolator is especially expensive in the components of the optical module and is larger in volume than a semiconductor element as another component, or for other reasons.

For example, Patent Document 1 and Non-patent Document 1 propose a technique for eliminating the need for an optical isolator. These documents propose optical modules which eliminate the need for an optical isolator by adopting a GC-DFB laser device. A reason why the need for an optical module is eliminated is that a GC-DFB laser device has characteristics of high stability in single longitudinal mode oscillation, little transitional output change, high tolerance to the reflected return light, and so on.

Patent Document 1 is Japanese Patent Application Kokai Publication No. 2003-133638.

Non-patent Document 1 is IEEE JOURNAL OF QUANTUM ELECTRONICS, Vol. 27, No. 6, June 1991, Y. Nakano et al., “Reduction of Excess Intensity Noise Induced by External Reflection in a Gain-Coupled Distributed Feedback Semiconductor Laser”, pp. 1732-1735.

### DISCLOSURE OF THE INVENTION

### Problem to be Solved by the Invention

However, since the conventional GC-DFB laser device has periodical structure of gain (loss), the output characteristics of the laser device are degraded, and as a result, there is a problem that an optical module adopting this DFB laser device cannot satisfy the specification of the output characteristics. To be concrete, the conventional GC-DFB laser device cannot be applied to an actual optical module, because if the reflection characteristics are improved, the output characteristics are degraded, whereas if the output characteristics are improved, the reflection characteristics are degraded. Accordingly, in general, users have no other option but to adopt an expensive optical module including an optical isolator in addition to an IC-DFB laser device with improved output characteristics.

The present invention has been made in order to resolve the above-described problems of the conventional art, and its object is to provide a DFB laser device that can reduce the influence of the reflected return light and improve the output characteristics and can provide a small-sized and inexpensive optical module if it is mounted in the optical module.

### Means for Solving the Problem

In order to attain the above-mentioned object, a distributed feedback semiconductor laser device according to the present invention is a GC-DFB laser device, which includes: a semiconductor substrate; a waveguide layer and an active layer which are formed on one surface side of the semiconductor substrate; and a diffraction grating structure provided on one surface of the waveguide layer and having a gain periodically varying in an optical waveguiding direction; wherein the active layer is disposed so as to adjoin the waveguide layer, a band gap wavelength of the waveguide layer is within ±0.1 μm of an oscillation wavelength of the active layer, a thickness of the waveguide layer is in a range of 5 nm to 30 nm, and a width of the active layer is in a range of 0.7 μm to 1.0 μm.

### EFFECTS OF THE INVENTION

Since the DFB laser device according to the present invention has the above-described structure, as can be made clear also from the below-described experimental data, when it is mounted in the optical module, there is little influence of the reflected return light from outside even if no optical isolator is provided. Accordingly, the DFB laser device according to the present invention satisfies the specification of GE-PON system defined as IEEE802.3ah standardization specification under a general usage condition, for example, a specification that a value of relative intensity noise (Relative Intensity Noise: RIN) is not more than −115 dB/Hz even when there is −15 dB external reflection that causes the reflected return light or other specifications. As described above, since the DFB laser device according to the present invention can reduce degradation of the reception sensitivity after transmission, it can be adopted to the GE-PON system. Further, since the optical module adopting the DFB laser device according to the present invention has no need for the optical isolator, there is an advantageous effect that a small-sized and inexpensive optical module can be provided.

### BRIEF DESCRIPTION OF THE DRAWINGS

FIG. 1A is a partially cut away perspective view schematically showing structure of a GC-DFB laser device according to the first embodiment of the present invention, and FIG. 1B is a partial cross-sectional view schematically showing only part of semiconductor laminated layers when the DFB laser device according to the first embodiment is cut in a direction perpendicular to a direction along the mesa stripe.

FIG. 2A is a diagram showing a relationship between a RIN and a power penalty, FIG. 2B is a diagram showing a relationship between a band gap wavelength and a RIN in an InGaAsP waveguide layer of the DFB laser device according to the present invention, and FIG. 2C is a diagram showing a relationship between a thickness and a RIN in an InGaAsP waveguide layer of the GC-DFB laser device according to the present invention.

FIG. 3 is a diagram showing a relationship between a width of the mesa stripe and a threshold current at high temperature operation in the DFB laser device according to the present invention.

FIG. 4 is a cross-sectional view showing structure of a GC-DFB laser device according to the second embodiment of the present invention.

### DESCRIPTION OF CHARACTERS

10, 10a DFB laser device; 100, 100a n-InP substrate; 102, 102a diffraction grating; 104, 104a InGaAsP waveguide layer; 106, 106a MQW active layer; 107a InP semiconductor layer; 108, 108a p-InP clad layer; 110, 110a p-InGaAs contact layer; 111 mesa stripe; 112 p-InP layer; 114 n-InP layer; 116 current blocking layer; 118, 118a double channels; 120 silicon nitride film; 122 contact hole; 124 p-type ohmic electrode; 126 n-type ohmic electrode.

### BEST MODE FOR CARRYING OUT THE INVENTION

A gain coupled (GC) distributed feedback semiconductor laser device (DFB laser device) according to the present invention will be described below with reference to the attached drawings. Further, the attached drawings schematically illustrate the shape, size and arrangement of each component as far as the present invention can be understood. Furthermore, numerical and other conditions described below are merely preferred examples, the present invention is not limited to only examples described below or shown in the drawings.

A GC-DFB laser device according to the present invention includes a semiconductor substrate, a waveguide layer and an active layer formed on one surface side of the semiconductor substrate, and a diffraction grating structure with a gain periodically varying in an optical waveguiding direction, wherein the active layer is disposed so as to adjoin the waveguide layer. Further, it is formed so that a band gap wavelength of the waveguide layer is within ±0.1 μm of the oscillation wavelength of the active layer, a thickness of the waveguide layer is in a range of 5 nm to 30 nm, and a width of the active layer is in a range of 0.7 μm to 1.0 μm. For example, the waveguide layer is an InGaAsP waveguide layer, and the active layer is composed of alternately laminated layers of an InGaAsP barrier layer and an InGaAsP well layer.

In a general example, the InGaAsP waveguide layer is formed on an InP substrate as a semiconductor substrate, the active layer is formed on the InGaAsP waveguide layer, and the diffraction grating structure with a periodically varying gain is a structure including a boundary between the InP substrate and the InGaAsP waveguide layer.

Further, in another example, the active layer is formed on an InP substrate as a semiconductor substrate, the InGaAsP waveguide layer is formed on the active layer, the InP semiconductor layer is formed on the InGaAsP waveguide layer, and the diffraction grating structure with a periodically varying gain is a structure including a boundary between the InGaAsP waveguide layer and the InP substrate.

### First Embodiment

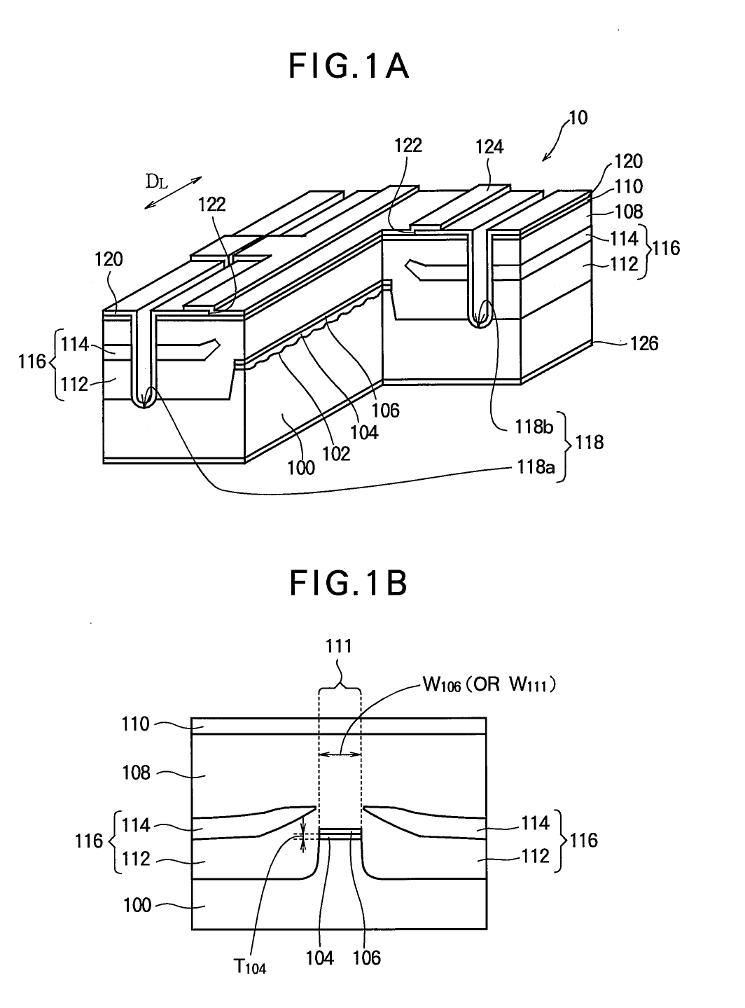

FIG. 1A is a partially cut away perspective view schematically showing structure of a GC-DFB laser device according to the first embodiment of the present invention, and FIG. 1B is a partial cross-sectional view schematically showing only part of semiconductor laminated layers when the DFB laser device according to the first embodiment is cut in a direction perpendicular to a direction along a mesa stripe. In FIGS. 1A and 1B, for the sake of easy understanding of the structure of the DFB laser device, no hatchings are drawn within cross-sectional surfaces. Further, this DFB laser device is a GC-DFB laser device, an oscillation wavelength of which is 1.3 μm.

As shown in FIG. 1A, the GC-DFB laser device 10 according to the first embodiment includes a semiconductor substrate 100, a waveguide layer 104 formed on one surface of this semiconductor substrate 100, an active layer 106 formed on the waveguide layer 104, and a diffraction grating structure 102 with a gain periodically varying in an optical waveguiding direction (a direction D_{L} in FIG. 1A). The diffraction grating structure 102 with the periodically varying gain is a structure including a boundary between the semiconductor substrate 100 and the waveguide layer 104. The semiconductor substrate 100 is, for example, an n-InP substrate. The waveguide layer 104 is, for example, an InGaAsP waveguide layer 104, a surface of which is made flat. The active layer 106 is, for example, a multi quantum well (Multi Quantum Well: MQW) active layer 106 including alternately laminated layers of the InGaAsP barrier layer and the InGaAsP well layer disposed on the InGaAsP waveguide layer 104. Further, a p-InP clad layer 108 and a p-InGaAs contact layer 110 are formed on the MQW active layer 106 in order. In the first embodiment, a band gap wavelength of the waveguide layer 104 is within ±0.1 μm of the oscillation wavelength of the active layer 106, a thickness of the waveguide layer 104 is in a range of 5 nm to 30 nm, and a width of the active layer 106 is in a range of 0.7 μm to 1.0 μm.

Further, as shown in FIG. 1B, a semiconductor multilayer region including sequentially laminated layers from diffraction grating structure 102 to the MQW active layer 106 is formed to a mesa stripe shape extending in a longitudinal direction (a direction D_{L} in FIG. 1A, that is, a direction perpendicular to a sheet on which FIG. 1B is drawn), and current blocking layers 116 each including sequentially laminated p-InP layer 112 and n-InP layer 114 are buried on both sides of the mesa stripe 111. Further, each of the semiconductor laminated layers is formed by the metal organic vapor phase epitaxy (Metal Organic Vapor Phase Epitaxy: MOVPE) method. As described above, a structure of the GC-DFB laser device 10 according to the first embodiment is a buried hetero (Buried Hetero: BH) structure.

Furthermore, as shown in FIG. 1A, double channels 118 including channels 118a and 118b, which are formed by etching to remove layers from the p-InGaAs contact layer 110 as an uppermost layer to part of surface side of the n-InP substrate 100, are formed in regions including the current blocking layers 116 on both outer sides of the mesa stripe 111.

Moreover, as shown in FIG. 1A, a p-type ohmic electrode 124 composed of AuZn that makes ohmic contact with the p-InGaAs contact layer 110 through a contact hole 122 of a silicon nitride film 120 is formed on the p-InGaAs contact layer 110. Part of the p-type ohmic electrode 124 extends outward the channel 118a disposed on the silicon nitride film 120. Further, a rear surface side of the n-InP substrate 100 is etched to be thinned, and after that, an n-type ohmic electrode 126 composed of AuGeNi/Au is formed on it.

Furthermore, the DFB laser device 10 according to the first embodiment is fabricated by determining a desired resonator length of the laser device, producing cleavages to form facets perpendicular to a longitudinal direction of the mesa stripe 111, and performing facet coating to control reflectivity of two opposite facets of the laser device. In the first embodiment, a resonator length is 350 μm, and the reflectances of two opposite facets subjected to the facet coating with respect to an oscillation wavelength are 1% on a side of an light emitting facet and 80 to 90% on a side of a backward facet.

As already has been described, the feature of the DFB laser device 10 according to the first embodiment is that a band gap wavelength of the waveguide layer 104 is within ±0.1 μm of the oscillation wavelength of the active layer 106 which is formed as an upper layer of the waveguide layer, a thickness T₁₀₄ of the waveguide layer 104 is in a range of 5 nm to 30 nm, and a width W₁₀₆ of the active layer 106 is in a range of 0.7 μm to 1.0 μm.

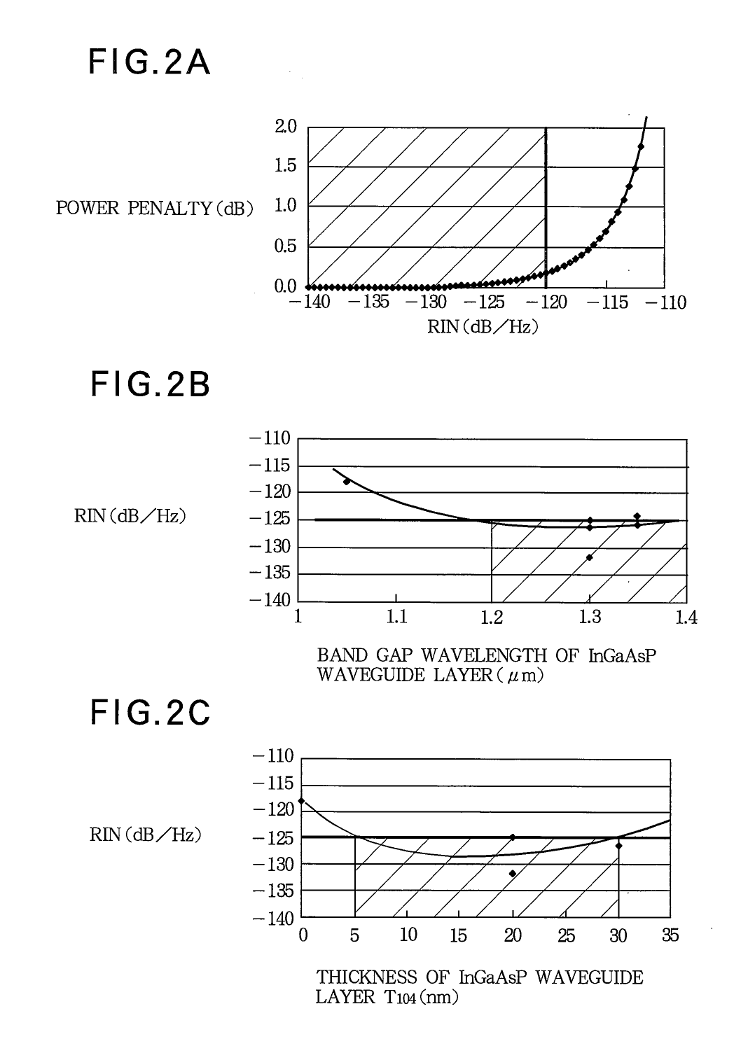

For this reason, a band gap wavelength and a thickness T₁₀₄ of the InGaAsP waveguide layer 104 in the first embodiment and a relative intensity noise (RIN) of the GC-DFB laser device 10 with an oscillation wavelength 1.3 μm in the first embodiment are measured in a similar method to that described in Non-patent Document 1. FIGS. 2A, 2B and 2C are diagrams for explaining results of their measurements.

FIG. 2A is a diagram showing a relationship between a RIN and a power penalty (degradation of reception sensitivity) after transmission, wherein the power penalty depends on a value of RIN. In FIG. 2A, a horizontal axis represents a value of the RIN in units of dB/Hz, and a vertical axis represents a value of the power penalty in units of dB. In general, it is known that in the 1.3 μm band optical communications, a value of the RIN is desirably not more than −120 dB/Hz. Therefore, as can be seen from FIG. 2A, a desirable value of the power penalty is not more than approximately 0.2 dB.

Further, FIG. 2B is a diagram showing a relationship between a band gap wavelength of the InGaAsP waveguide layer 104 and a RIN in a state where the reflected return light at an intensity of −15 dB impinging on the output facet of the DFB laser device 10 according to the first embodiment, that is, in an actual condition which is a condition where there is the reflected light of external reflection of −15 dB as the above-described GE-PON system specification. In FIG. 2B, a horizontal axis represents a band gap wavelength of the InGaAsP waveguide layer 104 in units of μm, and a vertical axis represents a value of the RIN of the DFB laser device 10 according to the first embodiment in units of dB/Hz. Although in the description with reference to FIG. 2A, it is described that a preferred value of the RIN is not more than −120 dB/Hz, in the description with reference to FIGS. 2B and 2C, in consideration of variations of actual measured values of the RIN, on the assumption that a standard deviation σ is approximately 1.7 dB/Hz, a condition where the 3σ (3-sigma region) does not exceed −120 dB/Hz is used as a preferred condition. For this reason, in the description of FIGS. 2B and 2C, a condition where a value of the RIN is not more than −125 dB/Hz is used as a preferred condition.

As can be understood from the result of measurements shown in FIG. 2B, a band gap wavelength of the InGaAsP waveguide layer 104 satisfying the condition that a value of the RIN is not more than −125 dB/Hz is in a range of 1.2 μm to 1.4 μm and is within ±0.1 μm of the oscillation wavelength 1.3 μm of the DFB laser device 10 according to the first embodiment.

On the other hand, FIG. 2C is a diagram showing a relationship between a thickness T₁₀₄ of the InGaAsP waveguide layer 104 and a RIN in a state where the reflected return light at the intensity of −15 dB is forced to enter the output facet of the DFB laser device 10 according to the first embodiment on above-described actual use condition. In FIG. 2C, a horizontal axis represents a thickness T₁₀₄ of the InGaAsP waveguide layer 104 in units of nm, and a vertical axis represents a value of the RIN of the DFB laser device 10 according to the first embodiment in units of dB/Hz. As can be seen from the result of measurements shown in FIG. 2C, a thickness T₁₀₄ of the InGaAsP waveguide layer 104 satisfying a preferred condition of a value of the RIN, that is, not more than −125 dB/Hz is in a range of 5 nm to 30 nm. A minimum value of the thickness T₁₀₄ of the InGaAsP waveguide layer 104 is restricted for reasons that a depth of the diffraction grating 102 is of the order of 5 nm to 20 nm, and the InGaAsP waveguide layer 104 needs to have a thickness of at least 5 nm in order to make the MQW active layer 106 of the InGaAsP waveguide layer 104 flat.

In the DFB laser device 10 according to the first embodiment, when a depth of the diffraction grating structure 102 is determined, a value of the coupling coefficient κ is set to be of the order of 40 to 60 cm⁻¹, and a resonator length of the laser device is L (cm), the optimization of the MQW active layer 106 and the InGaAsP waveguide layer 104 is performed so that a value of the normalized coupling coefficient κL becomes approximately in a range of 1 to 2. Further, the optimization of the MQW active layer 106 and the InGaAsP waveguide layer 104 is performed so as to make a ratio of absolute values of an imaginary component κᵢ and a real component κᵣ of a coupling coefficient κ, which is expressed by κ=κᵣ+iκᵢ, that is, |κᵢ|/|κᵣ| to be approximately a range of 0.01 to 0.1.

As has been described above, in the DFB laser device 10 according to the first embodiment, the optimization of the band gap wavelength and the thickness T₁₀₄ of the InGaAsP waveguide layer 104 disposed on the diffraction grating 102 is performed in order to reduce the influence due to the reflected return light.

As already has been described, it is difficult to obtain output characteristics satisfying an actual use condition in the GC-DFB laser device, because the diffraction grating structure is formed by the periodically varying gain (or loss) structure. For this reason, in the present invention, in order to improve the output characteristics of the GC-DFB laser device, the optimization of the width W₁₁₁ of the mesa stripe 111, which is the width W₁₀₆ of the MQW active layer 106 shown in FIG. 1B, is also performed.

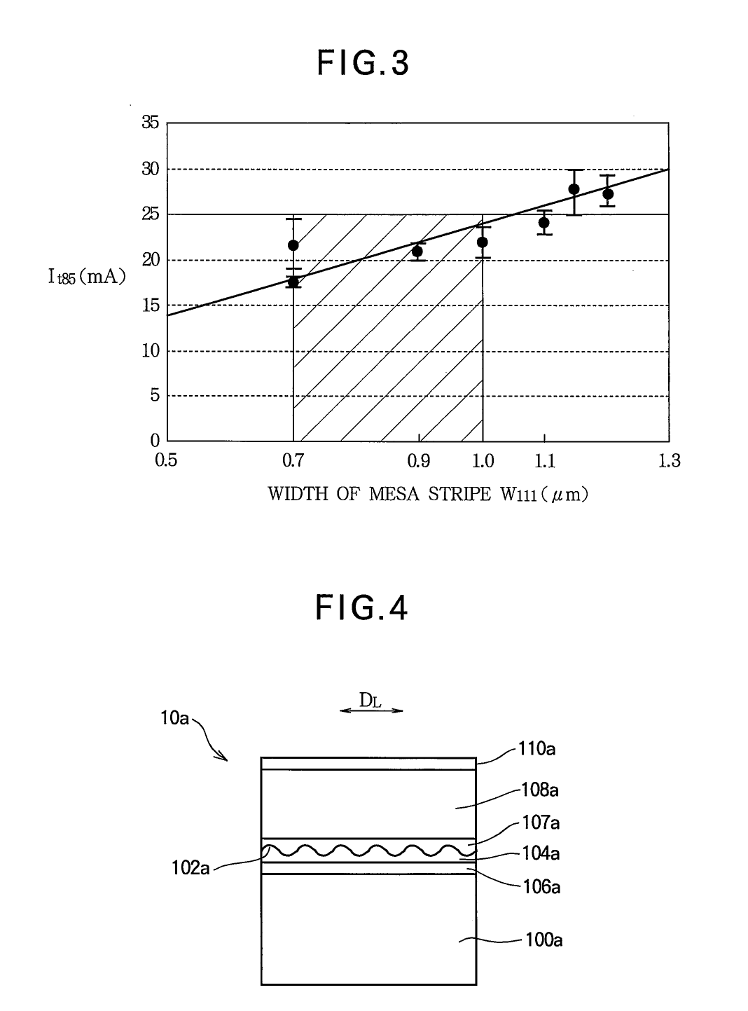

A relationship between the width W₁₁₁ of the mesa stripe 111, which is the width W₁₀₆ of the MQW active layer 106, in the DFB laser device 10 according to the first embodiment and a threshold current during the operation at high temperature (at 85° C.) as one of the output characteristics is shown in FIG. 3. In FIG. 3, a horizontal axis represents the width W₁₁₁ of the mesa stripe 111 in units of μm, and a vertical axis represents a threshold current Iₜ₈₅ at 85° C. in the DFB laser device 10 according to the first embodiment in units of mA.

As can be seen from FIG. 3, if a normal use condition is taken into consideration, there is a requirement that a value of the threshold current Iₜ₈₅ should be not more than 25 mA even when it operates at a high temperature of approximately 85° C. This requirement can be attained by setting the width W₁₁₁ of the mesa stripe 111 to a value not more than 1.0 μm. Further, although the result of measurements shown in FIG. 3 cannot be applied to other embodiments as it is, because it is influenced by the structure of the active layer, the resonator length, and so on, other embodiments also have a similar tendency in a relationship between a width of the mesa stripe and a threshold current.

Furthermore, in the result of measurements shown in FIG. 3, the increase of the threshold current due to the decrease of confinement of light is not considered. In practical, since the threshold current increases when the width W₁₁₁ of the mesa stripe 111 is too small and part of the mesa stripe 111 is fragile when the width W₁₁₁ of the mesa stripe 111 is too small, thereby deteriorating the reproducibility and yield in manufacturing process, it is desirable that a value of the width W₁₁₁ of the mesa stripe 111 be not less than 0.7 μm.

As can be understood from the above results, it is preferable that the width W₁₁₁ of the mesa stripe 111, that is, the width W₁₀₆ of the MQW active layer 106 in the DFB laser device 10 according to the first embodiment be in a range of 0.7 μm to 1.0 μm.

As has been made clear from the above description, the DFB laser device 10 according to the first embodiment reduces the influence of the reflected return light by performing the optimization of the band gap wavelength and the film thickness T₁₀₄ of the InGaAsP waveguide layer 104 disposed on the diffraction grating 102, and improves the degradation of output characteristics resulting from it by performing the optimization of the width W₁₁₁ of the mesa stripe 111, that is, the width W₁₀₆ of the active layer 106.

The characteristics of the DFB laser device 10 according to the optimized embodiment is that when the normalized coupling coefficient κL is a value of 1.3, and the CW oscillation (continuous wave oscillation) occurs in a single longitudinal mode at an operating temperature of a range of 0° C. to 90° C. Further, in the DFB laser device 10 according to the optimized embodiment, the threshold current and slope efficiency are 4.5 mA and 0.44 W/A at 25° C., and 19.2 mA and 0.20 W/A at 85° C. Furthermore, in the DFB laser device 10 according to the optimized embodiment, a side mode suppression ratio (Side Mode Suppression Ratio: SMSR) indicating a ratio of oscillations of a dominant mode and a side mode is 40 dB or more even when the output is 15 mW at 90° C., the oscillation characteristics of the single longitudinal mode that is stable even at a high temperature can be obtained.

### Second Embodiment

FIG. 4 is a diagram schematically showing a cross sectional view of a DFB laser device 10a according to the second embodiment of the present invention. As shown in FIG. 4, the GC-DFB laser device 10a according to the second embodiment includes a semiconductor substrate 100a, an active layer 106a formed on one surface of the semiconductor substrate 100a, a waveguide layer 104a formed on this active layer 106a, a semiconductor layer 107a formed on the waveguide layer 104a, and a diffraction grating structure 102a with a gain periodically varying in an optical waveguiding direction (a direction D_{L} in FIG. 2). The diffraction grating structure 102a with a periodically varying gain is a structure including a boundary between the waveguide layer 104a and the semiconductor layer 107a. The semiconductor substrate 100a is, for example, an n-InP substrate. The active layer 106a is, for example, an MQW active layer including alternately laminated InGaAsP barrier layer and InGaAsP well layer. The waveguide layer 104a is, for example, an InGaAsP waveguide layer. The semiconductor layer 107a is, for example, an InP semiconductor layer. Further, a p-InP clad layer 108a and a p-InGaAs contact layer 110a are formed on the InP semiconductor layer 107a in this order. Furthermore, a band gap wavelength of the waveguide layer 104a is within ±0.1 μm of the oscillation wavelength of the active layer 106a, a thickness of the waveguide layer 104a is in a range of 5 nm to 30 nm, and a width of the active layer 106a is in a range of 0.7 μm to 1.0 μm.

Although the DFB laser device 10a according to the second embodiment and the DFB laser device 10 according to the first embodiment are different in the order of arrangement of each layer, they are common in a point that the diffraction grating structure and the MQW active layer are laminated. For this reason, if similar conditions in the DFB laser device 10 according to the first embodiment are applied to the DFB laser device 10a according to the second embodiment, similar effects can be obtained.

Further, except for the above-described points, the second embodiment is the same as the first embodiment.

### MODIFIED EXAMPLES

Although a case where the n-InP substrate is used as the semiconductor substrate has been described in the above description, the present invention is not limited to this example and can be applied to another example that includes a p-InP substrate instead of the n-InP substrate and a multilayered member disposed on the InP substrate the having a reverse conductivity type.

Further, in the above description, a case where a periodical structure of the diffraction grating is a uniform structure has been described, the present invention is not limited such example and can also be applied to a diffraction grating structure having the λ/4 shift structure.

Furthermore, in the above description, the GC-DFB laser device with the oscillation wavelength of 1.3 μm band has been described, the present invention is not limited to such example and can also be applied to another GC-DFB laser device with another oscillation wavelength band such as 1.55 μm band or 1.49 μm band.

Moreover, in the above description, the BH-structured GC-DFB laser device has been described, the present invention is not limited to such example and can also be applied to a ridge waveguide type GC-DFB laser device.

What is claimed is:

1. A gain coupled distributed feedback semiconductor laser device comprising:
a semiconductor substrate;
a waveguide layer and an active layer which are formed on one surface side of the semiconductor substrate; and
a diffraction grating structure provided on one surface of the waveguide layer and having a gain periodically varying in an optical waveguiding direction;
wherein:
the active layer is disposed so as to adjoin the waveguide layer;
a band gap wavelength of the waveguide layer is within ±0.1 μm of an oscillation wavelength of the active layer;
a thickness of the waveguide layer is in a range of 5 nm to 30 nm; and
a width of the active layer is in a range of 0.7 μm to 1.0 μm.

2. The distributed feedback semiconductor laser device according to claim 1, wherein:
the waveguide layer is formed on the semiconductor substrate;
the active layer is formed on the waveguide layer; and
the diffraction grating structure is a structure including a boundary between the semiconductor substrate and the waveguide layer.

3. The distributed feedback semiconductor laser device according to claim 2, wherein:
the semiconductor substrate is an InP substrate;
the waveguide layer is an InGaAsP waveguide layer; and
the active layer is composed of alternately laminated layers of an InGaAsP barrier layer and an InGaAsP well layer.

4. The distributed feedback semiconductor laser device according to claim 1, wherein:
the active layer is formed on the semiconductor substrate; and
the waveguide layer is formed on the active layer;
the distributed feedback semiconductor laser device further comprising a semiconductor layer disposed on the waveguide layer;
wherein the diffraction grating structure is a structure including a boundary between the waveguide layer and the semiconductor layer.

5. The distributed feedback semiconductor laser device according to claim 4, wherein:
the active layer is composed of alternately laminated layers of an InGaAsP barrier layer and an InGaAsP well layer;
the waveguide layer is an InGaAsP waveguide layer; and
the semiconductor layer is an InP semiconductor layer.
